(19) United States
(12) Patent Application Publication
(10) Pub. No.: US 2026/0180197 A1
(43) Pub. Date: Jun. 25, 2026

(54) ELECTROMAGNETIC-WAVE REFLECTING PANEL, ELECTROMAGNETIC-WAVE REFLECTING APPARATUS USING SAME, ELECTROMAGNETIC-WAVE REFLECTING FENCE, METHOD FOR MANUFACTURING ELECTROMAGNETIC-WAVE REFLECTING PANEL, AND METHOD FOR EVALUATING ELECTROMAGNETIC-WAVE REFLECTING PANEL

(71) Applicant: AGC Inc., Tokyo (JP)

(72) Inventor: Kumiko KAMBARA, Tokyo (JP)

(73) Assignee: AGC Inc., Tokyo (JP)

(21) Appl. No.: 19/541,299

(22) Filed: Feb. 16, 2026

Related U.S. Application Data
(63) Continuation of application No. PCT/JP2024/027613, filed on Aug. 1, 2023.

(30) Foreign Application Priority Data
Aug. 21, 2023 (JP) 2023-134113

(51) Int. Cl. H01Q 15/14

(52) U.S. Cl. CPC H01Q 15/14; H01Q 15/141

(57) ABSTRACT

An electromagnetic-wave reflecting panel which satisfies long-term durability, an electromagnetic-wave reflecting apparatus using the same, an electromagnetic-wave reflecting fence, a method for manufacturing such an electromagnetic-wave reflecting panel, and a method for evaluating such an electromagnetic-wave reflecting panel are provided. An electromagnetic-wave reflecting panel is configured to reflect an electromagnetic wave in a predetermined frequency band of 1 MHz to 300 GHz, and includes: a reflecting function layer configured to selectively reflect the electromagnetic wave in the predetermined frequency band; and a dielectric resin substrate configured to support the layer, in which an amount of change in visible-light transmittance of the panel after putting the panel in an environment of a temperature of 40° C. to 80° C. for 2 to 720 hours, or in an environment of a temperature of 50° C. and a humidity of 95% for 2 to 720 hours is 10% or smaller, and ΔE*ab is 3.0 or smaller.

### INCORPORATION BY REFERENCE

This application is based upon and claims the benefit of priority from Japanese patent application No. 2023-134113, filed on Aug. 21, 2023, and PCT application No. PCT/JP2024/027613 filed on Aug. 1, 2024, the dis closure of which is incorporated herein in its entirety by reference.

### BACKGROUND

The present invention relates to an electromagnetic-wave reflecting panel, an electromagnetic-wave reflecting apparatus using the same, an electromagnetic-wave reflecting fence, and a method for manufacturing an electromagnetic-wave reflecting panel.

In order to implement various use cases such as automation of manufacturing processes and office work, remote control, introduction of control and management using AI (Artificial Intelligence), and unattended operations, base stations have been increasingly introduced into indoor and outdoor facilities. Examples of indoor and outdoor facilities include factories, plants, offices, commercial facilities, medical sites, event venues, highways, and railway lines. In 5th Generation Mobile Communication System (Hereinafter referred to as “5G”), which enables a large number of high-speed, large-capacity, and low-latency connections to be simultaneously performed, frequency bands of 6 GHz or lower called “sub-6” and a 28 GHz band which is classified into millimeter-wave bands are provided. It is expected that the frequency bands will be extended to terahertz bands in the next-generation 6G mobile communication standards. By using such high-frequency bands, the communication bandwidth is expanded, thus enabling a large amount of data communication to be performed with small delay. However, a high-frequency radio wave has a strong property of traveling in a straight line and hence cannot go around to a blinded area, so that it is necessary to use a reflector or the like. It has been proposed that electromagnetic-wave reflecting apparatuses be disposed along at least parts of production lines in factories (see, e.g., International Patent Publication No. WO2021/199504).

### SUMMARY

When an electromagnetic-wave reflecting panel is installed, a substate made of a flame-retardant resin may be used while taking impact resistance, a weight, and the like of the panel into consideration. When an electromagnetic-wave reflecting panel using such a resin substrate is used indoors or outdoors, it is necessary to satisfy the standards in regard to the long-term durability of safety glasses specified in JIS R3211, JIS R3213, etc. When an electromagnetic-wave reflecting panel using a resin substrate is subjected to a heat-resistance test described in the aforementioned standards, bubbles and/or swellings may be formed in the panel. Such bubbles and swellings affect the transmittance of the electromagnetic-wave reflecting panel and the visibility therethrough.

One of the objects of the present invention to provide an electromagnetic-wave reflecting panel which satisfies long-term durability, an electromagnetic-wave reflecting apparatus using the same, an electromagnetic-wave reflecting fence, a method for manufacturing such an electromagnetic-wave reflecting panel, and a method for evaluating such an electromagnetic-wave reflecting panel.

An electromagnetic-wave reflecting panel according to an embodiment is an electromagnetic-wave reflecting panel configured to reflect an electromagnetic wave in a predetermined frequency band of 1 MHz or higher and 300 GHz or lower, comprising: a reflecting function layer configured to selectively reflect the electromagnetic wave in the predetermined frequency band; and a dielectric resin substrate configured to support the reflecting function layer, wherein an amount of change in visible-light transmittance of the electromagnetic-wave reflecting panel after an endurance test in which the electromagnetic-wave reflecting panel is put in a constant-temperature bath having a temperature of 40° C. to 80° C. for 2 to 720 hours or in a constant-temperature and constant-humidity bath having a temperature of 50° C. and a humidity of 95% for 2 to 720 hours is 10% or smaller, and ΔE*ab is 3.0 or smaller.

An electromagnetic-wave reflecting panel which satisfies long-term durability, an electromagnetic-wave reflecting apparatus using the same, an electromagnetic-wave reflecting fence, a method for manufacturing such an electromagnetic-wave reflecting panel, and a method for evaluating such an electromagnetic-wave reflecting panel are provided.

The above and other objects, features and advantages of the present disclosure will become more fully understood from the detailed description given hereinbelow and the accompanying drawings.

### BRIEF DESCRIPTION OF DRAWINGS

FIG. 1 is a schematic view of an electromagnetic-wave reflecting apparatus using an electromagnetic-wave reflecting panel according to an embodiment;

FIG. 2 is a schematic view of an electromagnetic-wave reflecting fence obtained by connecting a plurality of electromagnetic-wave reflecting apparatuses with one another;

FIG. 3 is a cross section showing an example of frames for holding electromagnetic-wave reflecting panels;

FIG. 4 is a schematic diagram of a layer structure of an electromagnetic-wave reflecting panel according to an embodiment;

FIG. 5 is a schematic diagram of a layer structure of an electromagnetic-wave reflecting panel according to an embodiment;

FIG. 6 is a photograph showing an external appearance of a sample of Example 7 after an endurance test;

FIG. 7 is a photograph showing an external appearance of a sample of Example 8 after an endurance test; and

FIG. 8 is a table in which conditions and measurement results of Examples 1 to 10 are summarized.

### DESCRIPTION OF EMBODIMENTS

An electromagnetic-wave reflecting panel is formed of a laminate of a plurality of materials. When an electromagnetic-wave reflecting panel using a substate made of a dielectric resin such as polycarbonate or acryl is subjected to an endurance test in conformity with the aforementioned standards, bubbles and/or swellings are formed in the panel. The inventors have found that, based on a hypothesis that the amount of gas containing moisture and the like contained in the resin substrate or the adhesiveness between the resin substrate and the adhesive layer is related to the bubbles and/or swellings that are formed in the panel, the long-term durability of the resin substrate can be improved by optimizing at least the conditions for preliminary annealing of the resin substrate. The long-term durability includes heat resistance, resistance to heat and humidity, and light stability (weather resistance). However, we have paid particular attention to heat resistance and resistance to heat and humidity.

An electromagnetic-wave reflecting panel according to an embodiment, an electromagnetic-wave reflecting apparatus using the same, an electromagnetic-wave reflecting fence, a method for manufacturing such an electromagnetic-wave reflecting panel, and a method for evaluating such an electromagnetic-wave reflecting panel will be described hereinafter with reference to the drawings. Embodiments shown below are examples for practically carrying out the technical concept of the invention, and the invention is not limited to processes and numerical values described below. The same reference numerals (or symbols) are assigned to components/structures having the same functions throughout the drawings, and redundant descriptions may be omitted. Partial replacements or combinations between different embodiments and configuration examples are possible. The size, positional relationship, and the like of each member shown in each drawing may be exaggerated in order to facilitate the understanding of the invention. The term “up” or “down” in the positional relationship refers to the up/down direction in the laminating direction or the film forming direction, and is not an absolute direction, unless otherwise specified.

### <Electromagnetic-Wave Reflecting Apparatus and Electromagnetic-Wave Reflecting Fence>

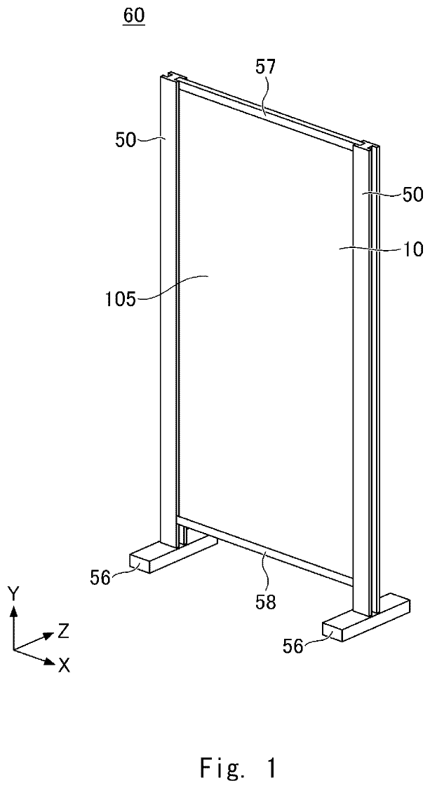

FIG. 1 is a schematic diagram of an electromagnetic-wave reflecting apparatus 60 using an electromagnetic-wave reflecting panel 10. The electromagnetic-wave reflecting panel 10 is manufactured while optimizing the conditions for preliminary annealing of a dielectric resin substrate used in the electromagnetic-wave reflecting panel 10, so that the transparency of the panel or the visibility therethrough is maintained even after a long-term endurance test. The surface of the resin substrate may be coated with a hard coat layer or a barrier coat layer. The electromagnetic-wave reflecting apparatus 60 includes the electromagnetic-wave reflecting panel 10 and frames 50 for holding the electromagnetic-wave reflecting panel 10. In the coordinate system shown in FIG. 1, in the state where the electromagnetic-wave reflecting apparatus 60 is installed, the width or horizontal direction of the electromagnetic-wave reflecting panel 10 is defined as an X direction; the height or vertical direction thereof is defined as a Y direction; and the thickness direction thereof is defined as a Z direction.

The electromagnetic-wave reflecting panel 10 includes a reflecting function layer (as will be described later), and reflects radio waves in a desired band selected from frequency bands of 1 MHz or higher and 300 GHz or lower. The band of radio waves that the electromagnetic-wave reflecting panel 10 reflects is more preferably a desired band of radio waves selected from frequency bands from 1 GHz to 300 GHz. The electromagnetic-wave reflecting panel 10 selectively reflects electromagnetic waves in a specific frequency band, but is transparent to visible light. At least a part of a reflecting surface 105 of the electromagnetic-wave reflecting panel 10 may include a metasurface whose reflection angle and reflection efficiency are controlled. The metasurface is formed of a designed periodic pattern, a mesh pattern, a geometric pattern, or the like according to how to reflect electromagnetic waves and/or the frequency band, and its reflection characteristics such as the reflection angle and the reflection efficiency are controlled. The control of the reflection angle includes the formation of non-specular reflection in which the incident angle and the reflection angle are different from each other, and the control of the diffusion direction. The reflecting surface 105 of the electromagnetic-wave reflecting panel 10 may be formed of a good conductor such as a metal or a transparent conductive film.

The electromagnetic-wave reflecting panel 10 has a specular reflecting surface in at least a part thereof. The specular reflecting surface reflects an incident electromagnetic wave in the direction of the same angle as its incident angle. A specular reflecting surface(s) and a non-specular reflecting surface(s) may be used in the reflecting surface of the electromagnetic-wave reflecting panel 10 in a mixed manner according to the place and/or the environment where the electromagnetic-wave reflecting apparatus 60 is installed. The specular reflecting surface can be formed of a metal mesh or a metal film having an aperture pattern smaller than the wavelengths of electromagnetic waves to be reflected.

The frames 50 hold two sides of the electromagnetic-wave reflecting panel 10 along the height direction when the electromagnetic-wave reflecting panel 10 is installed. In addition to the frames 50, a top frame 57 for holding the upper end of the electromagnetic-wave reflecting panel 10 and a bottom frame 58 for holding the lower end thereof may be provided. In this case, the frames 50, the top frame 57, and the bottom frame 58 constitute a frame for holding the whole peripheral edges of the electromagnetic-wave reflecting panel 10. The frames 50 may be referred to as “side frames” because of the positional relationship with respect to the top and bottom frames 57 and 58.

The electromagnetic-wave reflecting apparatus 60 may include leg parts 56 for supporting the frames 50. As shown in FIG. 1, in the case where the electromagnetic-wave reflecting apparatus 60 is erected on an installation surface by itself, the electromagnetic-wave reflecting apparatus 60 is preferably equipped with the leg parts 56, but the leg parts 56 are not indispensable. The leg parts 56 may be made movable by providing them with casters. Alternatively, the electromagnetic-wave reflecting panel 10 may be installed on a wall surface without providing it with the leg parts 56, or may be hung from the ceiling or a support.

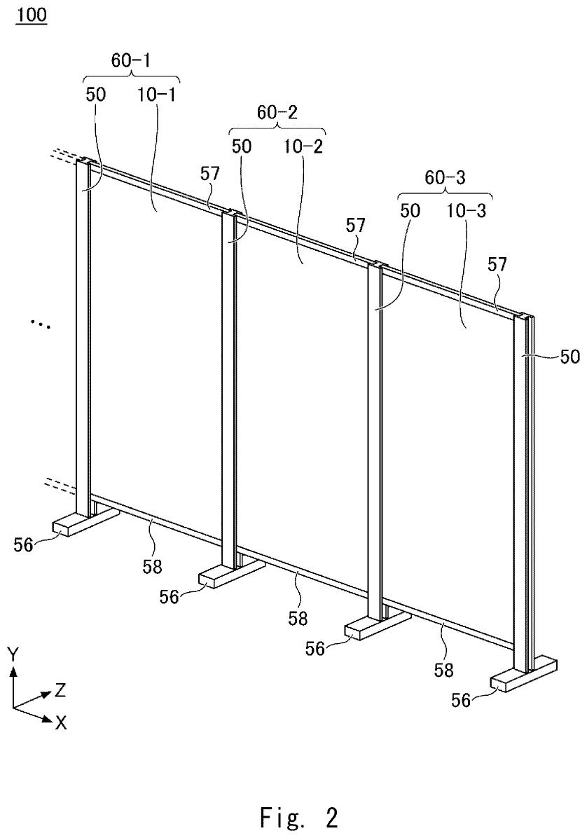

FIG. 2 is a schematic view of an electromagnetic-wave reflecting fence 100 obtained by connecting electromagnetic-wave reflecting apparatuses 60-1, 60-2, and 60-3 with one another. In FIG. 2, the electromagnetic-wave reflecting fence 100 is formed by connecting three electromagnetic-wave reflecting apparatuses 60-1, 60-2, and 60-3 (hereinafter, they may be collectively referred to as “electromagnetic-wave reflecting apparatuses 60” as appropriate), but the number of electromagnetic-wave reflecting apparatuses 60 to be connected is not limited to any particular number.

The electromagnetic-wave reflecting apparatuses 60-1, 60-2, and 60-3 include electromagnetic-wave reflecting panels 10-1, 10-2, and 10-3, respectively. The electromagnetic-wave reflecting fence 100 in which electromagnetic-wave reflecting panels are connected with one anther in the X direction can be obtained by supporting electromagnetic-wave reflecting panels adjacent to each other by a frame 50. In each of the electromagnetic-wave reflecting panels 10-1, 10-2, and 10-3 (hereinafter, they may be collectively referred to as “electromagnetic-wave reflecting panels 10” as appropriate), the conditions for preliminary annealing of the resin substrate are optimized, so that they have transparency or excellent visibility (i.e., visibility through the panel) even after a long-term endurance test.

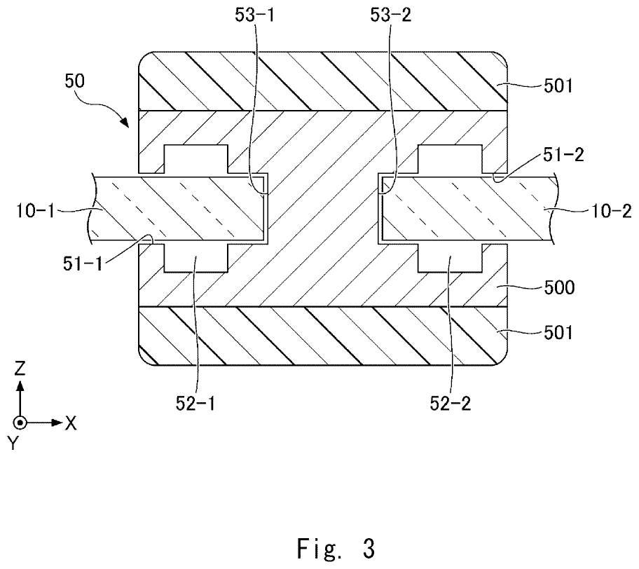

FIG. 3 shows an example of a configuration of the frame 50 in a cross section parallel to the XZ plane. The frame 50 includes a conductive main part 500 and slits 51-1 and 51-2 formed on both sides of the main part 500 in the width direction (X direction). Spaces 52-1 and 52-2, which communicate with the slits 51-1 and 51-2, respectively, and grooves 53-1 and 53-2 are formed inside the main part 500. The edge of the electromagnetic-wave reflecting panel 10-1 is inserted into the slit 51-1, passes through the space 52-1, and is held in the groove 53-1. Similarly, the edge of the electromagnetic-wave reflecting panel 10-2 is inserted into the slit 51-2, passes through the space 52-2, and is held in the groove 53-2. The spaces 52-1 and 52-2 are not indispensable. However, it is possible to reduce the weight of the main part 500 of the frame 50 and provide some margin to the holding angles of the electromagnetic-wave reflecting panels 10-1 and 10-2 by providing the spaces 52-1 and 52-2.

By inserting the electromagnetic-wave reflecting panels 10-1 and 10-2 into the grooves 53-1 and 53-2 through the slits 51-1 and 51-2, the electromagnetic-wave reflecting panels 10-1 and 10-2, which are adjacent to each other, are stably held, and the electromagnetic-wave reflecting fence 100 is assembled. A part of the main part 500 may be formed of a non-conductive material. A non-conductive cover 501 made of resin or the like may be provided on the outer surface of the main part 500, but the cover 501 is not indispensable. When the cover 501 is provided, the cover 501 may function as a protective member for protecting the frame 50.

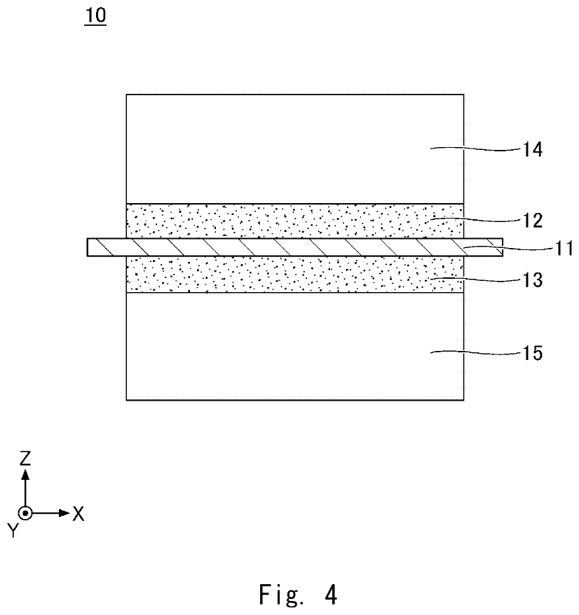

FIG. 4 shows an example of a layer structure of the electromagnetic-wave reflecting panel 10. This layer structure is a structure in the thickness (Z) direction of the electromagnetic-wave reflecting panel 10. The electromagnetic-wave reflecting panel 10 includes a reflecting function layer 11 and resin substrates 14 and 15 bonded to both surfaces of the reflecting function layer 11 by adhesive layers 12 and 13. The reflecting function layer 11 is formed of a conductive material and constitutes a reflecting surface that reflects electromagnetic waves in a specific frequency band selected a frequency range of 1 MHz or higher and 300 GHz or lower. As the material of the reflecting function layer 11, stainless steel, mild steel, copper, copper oxide, nickel, nickel oxide, gold, silver, aluminum, or a combination thereof can be used. The reflecting function layer 11 may be a conductive layer having a predetermined aperture pattern. The aperture pattern may consist of rectangular, circular, elliptical, or polygonal through apertures, or may be a mesh aperture. The selectivity of reflection for specific frequencies may be improved by forming a reflecting function layer 11 having a periodic aperture pattern.

The resin substrates 14 and 15 are formed of a dielectric transparent resin such as polycarbonate, flame-retardant acryl, cycloolefin polymer (COP), polyethylene terephthalate (PET), or fluoroplastic. When the electromagnetic-wave reflecting panel 10 is used in a production line, or is used indoors and outdoors, it is desired that the electromagnetic-wave reflecting panel 10 have a certain strength (impact resistance) as well as transparency or visibility (i.e., visibility through the panel). In order to reduce the total amount of the electromagnetic-wave reflecting panel 10 as much as possible while maintaining the strength of the electromagnetic-wave reflecting panel 10, the thicknesses of the resin substrates 14 and 15 are selected as appropriate in a range of 1.0 mm or larger and 10.0 mm or smaller.

The resin substrates 14 and 15 are preliminarily annealed under predetermined conditions before they are subjected to the lamination process in which they are laminated on the reflecting function layer 11 using adhesive layers 12 and 13, and as a result, the amount of moisture contained in the resin substrates 14 and 15 has been reduced. As will be described later, coating may be provided on the surface of the resin substrate 14 or 15. The adhesive layers 12 and 13 are dielectric adhesive layers, and ethylene vinyl acetate (EVA), COP, an ultraviolet-curable resin, a thermosetting resin, a thermoplastic resin, or the like may be used therefor. A urethane resin, an acrylic resin, a silicone resin, an epoxy resin, urethane acrylate, or the like may be used as the ultraviolet-curable resin. The materials of the adhesive layers 12 and 13 may be the same as each other or different from each other. However, the adhesive layers 12 and 13 are preferably formed of the same material, so that the electromagnetic-wave reflecting panel 10 can be used with the same reflection characteristics from either direction without distinguishing between the front surface and the rear surface of the electromagnetic-wave reflecting panel 10.

Regarding the materials of the adhesive layers 12 and 13, their relative dielectric constants and dielectric loss tangents are set in ranges appropriate for suppressing the decrease in reflection efficiency. For example, the relative dielectric constants of the adhesive layers 12 and 13 are 2.0 or higher and lower than 3.0, and the dielectric loss tangent is 0.0001 or higher and lower than 0.1000. When the relative dielectric constants of the adhesive layers 12 and 13 are 3.0 or higher, the loss in high frequencies may increase. When the dielectric loss tangents of the adhesive layers 12 and 13 are 0.1000 or higher, the loss of electric energy in the resin film may increase.

The electromagnetic-wave reflecting panel 10 having the above-described layer structure uses the resin substrates 14 and 15, which are preliminary annealed under the predetermined conditions, and the absolute value of the amount of change in transmittance is 10.0% or smaller, preferably 5% or smaller, more preferably 2.5% or smaller, and still more preferably 1.0% or smaller even after an endurance test that is carried out in a constant-temperature bath having a temperature of 80° C. up to 720 hours. Further, a color difference (ΔE*ab) after the same endurance test is 3.0 or smaller, preferably 2.0 or smaller, more preferably 1.5 or smaller, and still more preferably 1.0 or smaller. Further, the absolute value of the amount of change in transmittance after an endurance test in which the electromagnetic-wave reflecting panel is put in a constant-temperature and constant-humidity bath having a temperature of 50° C. and a humidity of 95% up to 720 hours is 10.0% or smaller, preferably 5.0% or smaller, and more preferably 2.5% or smaller. Further, the color difference (ΔE*ab) is 3.0 or smaller, preferably 2.0 or smaller, more preferably 1.5 or smaller, and still more preferably 1.0 or smaller.

Hereinafter, the change in visible-light transmittance after an endurance test and the color difference (ΔE*ab) are measured by a method for evaluating an electromagnetic-wave reflecting panel based on the layer structure shown in FIG. 4 while changing the conditions (temperature and time) for the preliminary annealing of the resin substrates.

The method for evaluating an electromagnetic-wave reflecting panel according to the present disclosure is an method for evaluating an electromagnetic-wave reflecting panel configured to reflect an electromagnetic wave in a predetermined frequency band of 1 MHz or higher and 300 GHz or lower, in which: the electromagnetic-wave reflecting panel includes a reflecting function layer configured to selectively reflect the electromagnetic wave in the predetermined frequency band, and a dielectric resin substrate configured to support the reflecting function layer; and it is evaluated whether an amount of change in visible-light transmittance of the electromagnetic-wave reflecting panel after an endurance test in which the electromagnetic-wave reflecting panel is put in a constant-temperature bath having a temperature of 40° C. to 80° C. for 2 to 720 hours or in a constant-temperature and constant-humidity bath having a temperature of 50° C. and a humidity of 95% for 2 to 720 hours is 10% or smaller, and whether ΔE*ab is 3.0 or smaller.

In each of Examples 1 to 6, Examples 9 and 10, and Examples 12 and 13 described below, the endurance test is a test in which a manufactured sample is put in a constant-temperature bath having a temperature of 40° C. to 80° C. for 2 to 720 hours. Specifically, the sample is put in a constant-temperature bath having a temperature selected from the group consisting of 40° C., 50° C., 60° C., 70° C., and 80° C. The endurance test in each of Examples 7 and 8 is a test in which a manufactured sample is put in a constant-temperature and constant-humidity bath having a temperature of 50° C. and a humidity of 95% for 2 to 720 hours. The materials and the thicknesses of the reflecting function layer 11 and the adhesive layers 12 and 13, which form the electromagnetic-wave reflecting panel, are the same as each other, and the materials and sizes of the resin substrates 14 and 15 are the same as each other. A stainless steel mesh having a thickness of 100 μm is used as the reflecting function layer 11, and a material made of ethylene vinyl acetate (EVA) and having a thickness of 400 μm is used as each of the adhesive layers 12 and 13. A polycarbonate (PC) sheet having a length of 1.0 m, a width of 2.0 m, and a thickness of 2.0 mm is used as each of the resin substrates 14 and 15.

### Example 1

Example 1 is Example 1 according to the present disclosure. Prior to the lamination process of an electromagnetic-wave reflecting panel having a layer structure shown in FIG. 4, a PC sheet having a length of 1.0 m, a width of 2.0 m, and a thickness of 2.0 mm was subjected to preliminary annealing at 80° C. for 20.0 hours. The amount of moisture contained in the PC sheet was measured by a moisture meter before and after the preliminary annealing. The amount of moisture in the PC sheet before the preliminary annealing was 3,500 ppm, and the amount of moisture in the PC sheet after the preliminary annealing, which was carried out at 80° C. for 20 hours, was 1,650 ppm. The amount of moisture in the PC sheet was reduced by 52.9% by the preliminary annealing. After 1.0 hours from when the PC sheet was taken out from the constant-temperature bath for the preliminary annealing, an electromagnetic-wave reflecting panel was manufactured by performing the lamination process. In the lamination process, a material made of EVA and having a thickness of 400 μm was provided on each of both surfaces of a stainless steel mesh having a thickness of 100 μm; the PC sheet, which had been subjected to the preliminary annealing, was bonded to each of both surfaces thereof; and a pressuring process was performed at 80° C. for 20 minutes. An electromagnetic-wave reflecting panel was obtained by this lamination process.

A sample having a size of 300 mm×300 mm was cut out from the manufactured electromagnetic-wave reflecting panel. The sample was cut out from the electromagnetic-wave reflecting panel, in conformity with a testing method specified in JIS R3212, in such a manner that one side of the sample coincided with the upper side of the electromagnetic-wave reflecting panel. The cut-out sample was put in a constant-temperature bath having a temperature of 80° C. Then, a 240-hour endurance test (A) and a 720-hour endurance test (B) were carried out. After each of the endurance tests, the external appearance of the sample was observed. Further, its visible-light transmittance and ΔE*ab were measured by an optical measuring instrument (spectrocolorimeter) manufactured by Shimadzu Corporation. A change (difference) from the visible-light transmittance measured in the remaining part of the electromagnetic-wave reflecting panel, from which the sample has been cut out, was calculated. As a result of the observation of the external appearance, any of bubbles, peeling, and swelling did not occur in the sample in both of the tests A and B. The change in visible-light transmittance after 240 hours was −0.5%, and ΔE*ab was 0.7. The change in visible-light transmittance after 720 hours was −0.7%, and ΔE*ab was 1.5.

### Example 2

Example 2 is Example 2 according to the present disclosure. A PC sheet having the same size as that of Example 1, i.e., having a length of 1.0 m, a width of 2.0 m, and a thickness of 2.0 mm was subjected to preliminary annealing at 120° C. for 2.5 hours. The amount of moisture contained in the PC sheet was measured by a moisture meter before and after the preliminary annealing. The amount of moisture in the PC sheet before the preliminary annealing was 3,550 ppm, and the amount of moisture in the PC sheet after the preliminary annealing, which was carried out at 120° C. for 2.5 hours, was 1,350 ppm. The amount of moisture in the PC sheet was reduced by 62.0% by the preliminary annealing. After 1.0 hours from when the PC sheet was taken out from the constant-temperature bath for the preliminary annealing, an electromagnetic-wave reflecting panel was manufactured by performing the lamination process as that performed in Example 1. A sample having a size of 300 mm×300 mm was cut out from the manufactured electromagnetic-wave reflecting panel. Then, a 240-hour endurance test (A) and a 720-hour endurance test (B) were carried out in a constant-temperature bath having a temperature of 80° C. After each of the endurance tests, the external appearance of the sample was observed. Further, its visible-light transmittance and ΔE*ab were measured. A change (difference) from the visible-light transmittance measured in the remaining part of the electromagnetic-wave reflecting panel, from which the sample has been cut out, was calculated. As a result of the observation of the external appearance, any of bubbles, peeling, and swelling did not occur in the sample in both of the tests A and B. The change in visible-light transmittance after 240 hours was-0.6%, and ΔE*ab was 1.0. The change in visible-light transmittance after 720 hours was −0.9%, and ΔE*ab was 1.4.

### Example 3

Example 3 is Example 3 according to the present disclosure. A PC sheet having the same size as that of Example 1, i.e., having a length of 1.0 m, a width of 2.0 m, and a thickness of 2.0 mm was subjected to preliminary annealing at 110° C. for 10.0 hours. The amount of moisture contained in the PC sheet was measured by a moisture meter before and after the preliminary annealing. The amount of moisture in the PC sheet before the preliminary annealing was 3,530 ppm, and the amount of moisture in the PC sheet after the preliminary annealing, which was carried out at 110° C. for 10 hours, was 1,450 ppm. The amount of moisture in the PC sheet was reduced by 58.9% by the preliminary annealing. After 1.0 hours from when the PC sheet was taken out from the constant-temperature bath for the preliminary annealing, an electromagnetic-wave reflecting panel was manufactured by performing the lamination process as that performed in Example 1. A sample having a size of 300 mm×300 mm was cut out from the manufactured electromagnetic-wave reflecting panel. Then, a 720-hour endurance test is carried out in a constant-temperature bath having a temperature of 80° C. After the endurance test, the external appearance of the sample was observed. Further, its visible-light transmittance and ΔE*ab were measured. A change (difference) from the visible-light transmittance measured in the remaining part of the electromagnetic-wave reflecting panel, from which the sample has been cut out, was calculated. As a result of the observation of the external appearance, any of bubbles, peeling, and swelling did not occur in the sample. Further, the change in visible-light transmittance was −0.4, and ΔE*ab was 0.4.

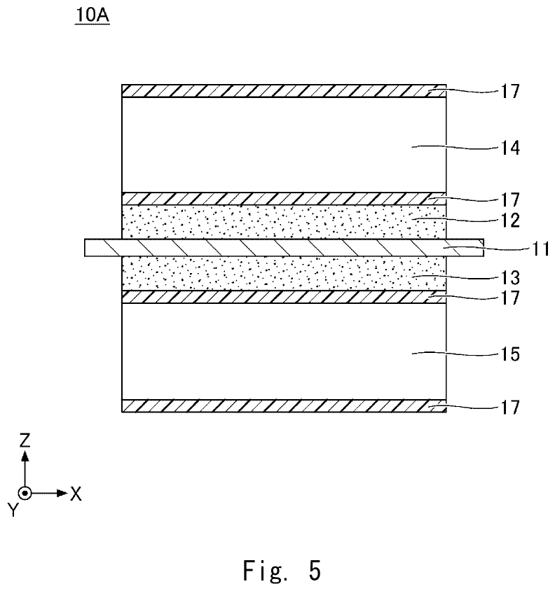

In each of Examples 4 to 6 described below, a hard coat was provided on the surface of the resin substrate. FIG. 5 shows a layer structure of an electromagnetic-wave reflecting panel 10A manufactured in each of Examples 4 to 6. The basic layer structure is the same as that shown in FIG. 4, and resin substrates 14 and 15 are bonded to both surfaces of the reflecting function layer 11 by adhesive layers 12 and 13. In each of the resin substrates 14 and 15, a hard coat layer 17 is provided on at least the surface of the resin substrate that is in contact with the adhesive layer 12 or 13. In the example shown in FIG. 5, the hard coat layer 17 is provided on each of both surfaces of each of the resin substrates 14 and 15. The hard coat layer 17 provided on the surface that is in contact with the adhesive layer 12 or 13 prevents moisture entering from the adhesive layer 12 or 13 into the resin substrate. In the resin substrate 14 or 15, the hard coat layer 17 provided on the surface opposite to the surface that is in contact with the adhesive layer 12 or 13 becomes the outermost layer of the electromagnetic-wave reflecting panel 10A. This hard coat layer 17 in the outermost layer prevents moisture entering from the external environment into the resin substrate 14 or 15 and functions as a protective layer of the electromagnetic-wave reflecting panel 10A. In Examples 4 to 6, endurance tests similar to those carried out in Examples 1 to 3 are carried out while changing the type of the hard coat.

### Example 4

Example 4 is Example 4 according to the present disclosure. A hard coat layer 17 was provided on each of both surfaces of a PC sheet having the same size as that of Example 1, i.e., having a length of 1.0 m, a width of 2.0 m, and a thickness of 2.0 mm. A urethane acrylate-based coat having a thickness of 8 μm was provided as the hard coat layer 17. The PC sheet including the urethane acrylate-based hard coat layer 17 on each of both surfaces thereof was subjected to preliminary annealing at 120° C. for 2.5 hours. The amount of moisture contained in the PC sheet was measured by a moisture meter before and after the preliminary annealing. The amount of moisture in the PC sheet before the preliminary annealing was 3,520 ppm, and the amount of moisture in the PC sheet after the preliminary annealing was 1,300 ppm. The amount of moisture in the PC sheet including the hard coats was reduced by 63.1% by the preliminary annealing. After 1.0 hours from when the PC sheet including the hard coats was taken out from the constant-temperature bath for the preliminary annealing, an electromagnetic-wave reflecting panel 10A was manufactured by performing the same lamination process as that performed in Example 1. In this case, the hard coat layer 17 was bonded to the adhesive layer 12 or 13. A sample having a size of 300 mm×300 mm was cut out from the manufactured electromagnetic-wave reflecting panel 10A. Then, a 720-hour endurance test was carried out in a constant-temperature bath having a temperature of 80° C. After each of the endurance tests, the external appearance of the sample was observed. Further, its visible-light transmittance and ΔE*ab were measured. A change (difference) from the visible-light transmittance measured in the remaining part of the electromagnetic-wave reflecting panel, from which the sample has been cut out, was calculated. As a result of the observation of the external appearance, any of bubbles, peeling, swelling, and the like did not occur in the sample. Further, the change in visible-light transmittance was −0.5, and ΔE*ab was 0.4.

### Example 5

Example 5 is Example 5 according to the present disclosure. The same urethane acrylate-based hard coat layer 17 as that of Example 4 was provided on each of both surfaces of a PC sheet having the same layer structure as that of Example 4 and having a length of 1.0 m, a width of 2.0 m, and a thickness of 2.0 mm. This PC sheet including the hard coats was subjected to preliminary annealing at 120° C. for 2.5 hours. After the PC sheet including the hard coats was taken out from the constant-temperature bath for the preliminary annealing and left in the environment for 5.0 hours, an electromagnetic-wave reflecting panel 10A was manufactured by performing the same lamination process as that performed in Example 4. The amount of moisture in the PC sheet before the preliminary annealing was 3,510 ppm, and the amount of moisture in the PC sheet immediately after the completion of the preliminary annealing was 1,320 ppm (reduced by 62.4%). Further, the amount of moisture in the PC sheet after being left in the environment for 5.0 hours was 2,080 ppm. Even after being left in the environment for 5.0 hours, the amount of moisture in the PC sheet was 40.7% smaller than that before the preliminary annealing. A sample having a size of 300 mm×300 mm was cut out from the manufactured electromagnetic-wave reflecting panel 10A. Then, a 720-hour endurance test was carried out in a constant-temperature bath having a temperature of 80° C. After each of the endurance tests, the external appearance of the sample was observed. Further, its visible-light transmittance and ΔE*ab were measured. A change (difference) from the visible-light transmittance measured in the remaining part of the electromagnetic-wave reflecting panel, from which the sample has been cut out, was calculated. As a result of the observation of the external appearance, any of bubbles, peeling, and swelling did not occur in the sample. Further, the change in visible-light transmittance was −0.5%, and ΔE*ab was 0.5.

Similarly to Example 4, the amount of moisture in the PC sheet of Example 5 was sufficiently reduced even when the preliminary annealing was performed for only 2 hours at 90° C. Further, since the hard coat layer 17 was provided on each of both surfaces of the PC sheet, moisture was prevented from entering the resin substrate even when the PC sheet was left in the environment for 5 hours after the preliminary annealing and before the lamination process was started, so that both the change in the transmittance and ΔE*ab were small.

### Example 6

Example 6 is Example 6 according to the present disclosure. A PC sheet of Example 6 has the same layer structure as that of Example 5, but a different type of hard coat layer 17 is provided. A silicone-based hard coat layer 17 having a thickness of 5 μm was provided on each of both surfaces of a PC sheet having a length of 1.0 m, a width of 2.0 m and a thickness of 2.0 mm. Then, this PC sheet including the hard coats was subjected to preliminary annealing at 120° C. for 2.5 hours. After the PC sheet including the hard coats was taken out from the constant-temperature bath for the preliminary annealing and left in the environment for 5.0 hours, an electromagnetic-wave reflecting panel 10A was manufactured by performing the same lamination process as those performed in Examples 4 and 5. The amount of moisture in the PC sheet before the preliminary annealing was 3,500 ppm, and the amount of moisture in the PC sheet immediately after the completion of the preliminary annealing was 1,350 ppm (reduced by 61.4%). Further, the amount of moisture in the PC sheet after being left in the environment for 5.0 hours was 2,020 ppm. Even after being left in the environment for 5.0 hours, the amount of moisture in the PC sheet was 42.2% smaller than that before the preliminary annealing.

A sample having a size of 300 mm×300 mm was cut out from the manufactured electromagnetic-wave reflecting panel 10A. Then, a 720-hour endurance test was carried out in a constant-temperature bath having a temperature of 80° C. After each of the endurance tests, the external appearance of the sample was observed. Further, its visible-light transmittance and ΔE*ab were measured. A change (difference) from the visible-light transmittance measured in the remaining part of the electromagnetic-wave reflecting panel, from which the sample has been cut out, was calculated. As a result of the observation of the external appearance, any of bubbles, peeling, and swelling did not occur in the sample. Further, the change in visible-light transmittance was −0.3%, and ΔE*ab was 0.3. By providing the silicone-based hard coat layer 17 on each of both surfaces of the PC sheet, the visible-light transmittance and the color became more stable than those in Example 5, and the durability was improved.

### Example 7

Example 7 is Example 7 according to the present disclosure. The conditions for the endurance tests were changed. Prior to the lamination process of an electromagnetic-wave reflecting panel having a layer structure shown in FIG. 4, a PC sheet having a length of 1.0 m, a width of 2.0 m, and a thickness of 2.0 mm was subjected to preliminary annealing at 80° C. for 20.0 hours. The amount of moisture contained in the PC sheet was measured by a moisture meter before and after the preliminary annealing. The amount of moisture in the PC sheet before the preliminary annealing was 3,500 ppm, and the amount of moisture in the PC sheet after the preliminary annealing, which was carried out at 80° C. for 20 hours, was 1,650 ppm. The amount of moisture in the PC sheet was reduced by 52.9% by the preliminary annealing. After 1.0 hours from when the PC sheet was taken out from the constant-temperature bath for the preliminary annealing, an electromagnetic-wave reflecting panel was manufactured by performing the lamination process. In the lamination process, a material made of EVA and having a thickness of 400 μm was provided on each of both surfaces of a stainless steel mesh having a thickness of 100 μm; the PC sheet, which had been subjected to the preliminary annealing, was bonded to each of both surfaces thereof; and a pressuring process was performed at 80° C. for 20 minutes. An electromagnetic-wave reflecting panel was obtained by this lamination process.

A sample having a size of 300 mm×300 mm was cut out from the manufactured electromagnetic-wave reflecting panel. The sample was cut out from the electromagnetic-wave reflecting panel, in conformity with a testing method specified in JIS R3212, in such a manner that one side of the sample coincided with the upper side of the electromagnetic-wave reflecting panel. The cut-out sample was put in a constant-temperature and constant-humidity bath having a temperature of 50° C. and a humidity of 95%, and a 240-hour endurance test was carried out. After each of the endurance tests, the external appearance of the sample was observed. Further, its visible-light transmittance and ΔE*ab were measured by an optical measuring instrument (spectrocolorimeter) manufactured by Shimadzu Corporation. A change (difference) from the visible-light transmittance measured in the remaining part of the electromagnetic-wave reflecting panel, from which the sample has been cut out, was calculated. As a result of the observation of the external appearance, any of bubbles, peeling, and swelling did not occur in the sample. Further, the change in visible-light transmittance was −2.0%, and ΔE*ab was 0.5.

### Example 8

Example 8 is Example 8 according to the present disclosure. In Example 8, the time during which the PC sheet was kept in the constant-temperature and constant-humidity bash is changed. Prior to the lamination process of an electromagnetic-wave reflecting panel having a layer structure shown in FIG. 4, a PC sheet having a length of 1.0 m, a width of 2.0 m, and a thickness of 2.0 mm was subjected to preliminary annealing at 80° C. for 20.0 hours. The amount of moisture contained in the PC sheet was measured by a moisture meter before and after the preliminary annealing. The amount of moisture in the PC sheet before the preliminary annealing was 3,500 ppm, and the amount of moisture in the PC sheet after the preliminary annealing, which was carried out at 80° C. for 20 hours, was 1, 650 ppm. The amount of moisture in the PC sheet was reduced by 52.9% by the preliminary annealing. After 1.0 hours from when the PC sheet was taken out from the constant-temperature bath for the preliminary annealing, an electromagnetic-wave reflecting panel was manufactured by performing the lamination process. In the lamination process, a material made of EVA and having a thickness of 400 μm was provided on each of both surfaces of a stainless steel mesh having a thickness of 100 μm; the PC sheet, which had been subjected to the preliminary annealing, was bonded to each of both surfaces thereof; and a pressuring process was performed at 80° C. for 20 minutes. An electromagnetic-wave reflecting panel was obtained by this lamination process.

A sample having a size of 300 mm×300 mm was cut out from the manufactured electromagnetic-wave reflecting panel. The sample was cut out from the electromagnetic-wave reflecting panel, in conformity with a testing method specified in JIS R3212, in such a manner that one side of the sample coincided with the upper side of the electromagnetic-wave reflecting panel. The cut-out sample was put in a constant-temperature and constant-humidity bath having a temperature of 50° C. and a humidity of 95%, and a 720-hour endurance test was carried out. After each of the endurance tests, the external appearance of the sample was observed. Further, its visible-light transmittance and ΔE*ab were measured by an optical measuring instrument (spectrocolorimeter) manufactured by Shimadzu Corporation. A change (difference) from the visible-light transmittance measured in the remaining part of the electromagnetic-wave reflecting panel, from which the sample has been cut out, was calculated. As a result of the observation of the external appearance, any of bubbles, peeling, and swelling did not occur in the sample, and the change in visible-light transmittance was −0.5%, and ΔE*ab was 0.7.

### Example 9

Example 9 is Example 9 according to the present disclosure. In Example 9, the time during which the PC sheet was kept in the constant-temperature and constant-humidity bash is changed. Prior to the lamination process of an electromagnetic-wave reflecting panel having a layer structure shown in FIG. 4, a PC sheet having a length of 1.0 m, a width of 2.0 m, and a thickness of 2.0 mm was subjected to preliminary annealing at 120° C. for 5.0 hours. The amount of moisture contained in the PC sheet was measured by a moisture meter before and after the preliminary annealing. The amount of moisture in the PC sheet before the preliminary annealing was 3,500 ppm, and the amount of moisture in the PC sheet after the preliminary annealing, which was carried out at 120° C. for 5 hours, was 1,150 ppm (reduced by 67.1%). After 1.0 hours from when the PC sheet was taken out from the constant-temperature bath for the preliminary annealing, an electromagnetic-wave reflecting panel was manufactured by performing the lamination process. In the lamination process, a material made of EVA and having a thickness of 400 μm was provided on each of both surfaces of a stainless steel mesh having a thickness of 100 μm; the PC sheet, which had been subjected to the preliminary annealing, was bonded to each of both surfaces thereof; and a pressuring process was performed at 80° C. for 20 minutes. An electromagnetic-wave reflecting panel was obtained by this lamination process.

A sample having a size of 300 mm×300 mm was cut out from the manufactured electromagnetic-wave reflecting panel. The sample was cut out from the electromagnetic-wave reflecting panel, in conformity with a testing method specified in JIS R3212, in such a manner that one side of the sample coincided with the upper side of the electromagnetic-wave reflecting panel. The cut-out sample for 40° C., the cut-out sample for 50° C., and the cut-out sample for 60° C. were put in constant-temperature baths having temperatures of 40° C., 50° C., and 60° C., respectively. Then, a 240-hour endurance test (A) and a 720-hour endurance test (B) were carried out for each of them. After each of the endurance tests, the external appearance of the sample was observed. Further, its visible-light transmittance and ΔE*ab were measured by an optical measuring instrument (spectrocolorimeter) manufactured by Shimadzu Corporation. A change (difference) from the visible-light transmittance measured in the remaining part of the electromagnetic-wave reflecting panel, from which the sample has been cut out, was calculated. As a result of the observation of the external appearances, any of bubbles, peeling, and swelling did not occur in the samples. Further, after 240 hours, the change in visible-light transmittance was −0.1% at 40° C., −0.2% at 50° C., and −0.2% at 60° C., and ΔE*ab was 0.1 at 40° C., 0.3 at 50° C., and 0.5 at 60° C. Further, after 720 hours, the change in visible-light transmittance was −0.1% at 40° C., −0.1% at 50° C., and +1.0% at 60° C., and ΔE*ab was 0.1 at 40° C., 0.2 at 50° C., and 0.6 at 60° C.

### Example 10

Example 10 is Example 10 according to the present disclosure. In Example 10, the time during which the PC sheet was kept in the constant-temperature and constant-humidity bash is changed. Prior to the lamination process of an electromagnetic-wave reflecting panel having a layer structure shown in FIG. 4, a PC sheet having a length of 1.0 m, a width of 2.0 m, and a thickness of 2.0 mm was subjected to preliminary annealing at 120° C. for 5.0 hours. The amount of moisture contained in the PC sheet was measured by a moisture meter before and after the preliminary annealing. The amount of moisture in the PC sheet before the preliminary annealing was 3,510 ppm, and the amount of moisture in the PC sheet after the preliminary annealing, which was carried out at 120° C. for 5 hours, was 1,140 ppm (reduced by 67.5%). After 1.0 hours from when the PC sheet was taken out from the constant-temperature bath for the preliminary annealing, an electromagnetic-wave reflecting panel was manufactured by performing the lamination process. In the lamination process, a material made of EVA and having a thickness of 400 μm was provided on each of both surfaces of a stainless steel mesh having a thickness of 100 μm; the PC sheet, which had been subjected to the preliminary annealing, was bonded to each of both surfaces thereof; and a pressuring process was performed at 80° C. for 20 minutes. An electromagnetic-wave reflecting panel was obtained by this lamination process.

A sample having a size of 300 mm×300 mm was cut out from the manufactured electromagnetic-wave reflecting panel. The sample was cut out from the electromagnetic-wave reflecting panel, in conformity with a testing method specified in JIS R3212, in such a manner that one side of the sample coincided with the upper side of the electromagnetic-wave reflecting panel. The cut-out sample was put in a constant-temperature bath having a temperature of 70° C., and a 48-hour endurance test was carried out. After each of the endurance tests, the external appearance of the sample was observed. Further, its visible-light transmittance and ΔE*ab were measured by an optical measuring instrument (spectrocolorimeter) manufactured by Shimadzu Corporation. A change (difference) from the visible-light transmittance measured in the remaining part of the electromagnetic-wave reflecting panel, from which the sample has been cut out, was calculated. As a result of the observation of the external appearance, any of bubbles, peeling, and swelling did not occur in the sample. Further, the change in visible-light transmittance was +0.3%, and ΔE*ab was 0.5.

### Example 11

Example 11 is Example 11 according to the present disclosure. In Example 11, the PC sheet was changed. A barrier coat layer having a thickness of 0.2 μm and having low permeability for water vapor and oxygen was provided on the surface of the PC sheet. Prior to the lamination process of an electromagnetic-wave reflecting panel having a layer structure shown in FIG. 4, a PC sheet having a length of 1.0 m, a width of 2.0 m, and a thickness of 2.0 mm was subjected to preliminary annealing at 80° C. for 5.0 hours. The amount of moisture contained in the PC sheet was measured by a moisture meter before and after the preliminary annealing. The amount of moisture in the PC sheet before the preliminary annealing was 3,510 ppm, and the amount of moisture in the PC sheet after the preliminary annealing, which was carried out at 80° C. for 5 hours, was 1,150 ppm (reduced by 67.5%). After 1.0 hours from when the PC sheet was taken out from the constant-temperature bath for the preliminary annealing, an electromagnetic-wave reflecting panel was manufactured by performing the lamination process. In the lamination process, a material made of EVA and having a thickness of 400 μm was provided on each of both surfaces of a stainless steel mesh having a thickness of 100 μm; the PC sheet, which had been subjected to the preliminary annealing, was bonded to each of both surfaces thereof; and a pressuring process was performed at 80° C. for 20 minutes. An electromagnetic-wave reflecting panel was obtained by this lamination process.

A sample having a size of 300 mm×300 mm was cut out from the manufactured electromagnetic-wave reflecting panel. The sample was cut out from the electromagnetic-wave reflecting panel, in conformity with a testing method specified in JIS R3212, in such a manner that one side of the sample coincided with the upper side of the electromagnetic-wave reflecting panel. The cut-out sample was put in a constant-temperature bath having a temperature of 70° C., and a 720-hour endurance test was carried out. After each of the endurance tests, the external appearance of the sample was observed. Further, its visible-light transmittance and ΔE*ab were measured by an optical measuring instrument (spectrocolorimeter) manufactured by Shimadzu Corporation. A change (difference) from the visible-light transmittance measured in the remaining part of the electromagnetic-wave reflecting panel, from which the sample has been cut out, was calculated. As a result of the observation of the external appearance, any of bubbles, peeling, and swelling did not occur in the sample. Further, the change in visible-light transmittance was −0.5%, and ΔE*ab was 0.8.

### Example 12

Example 12 is Comparative Example 1. In Example 12, an electromagnetic-wave reflecting panel 10 having a layer structure shown in FIG. 4 was manufactured by using the same PC sheet as that of Example 1. No hard coat layer 17 was provided on the PC sheet. Prior to the lamination process, the PC sheet was subjected to preliminary annealing at 80° C. for 20.0 hours. After 25.0 hours from when the PC sheet was taken out from the constant-temperature bath for the preliminary annealing, an electromagnetic-wave reflecting panel 10 was manufactured by performing the same lamination process as that performed in Example 1. The amount of moisture in the PC sheet before the preliminary annealing was 3,510 ppm, and the amount of moisture in the PC sheet immediately after the completion of the preliminary annealing was 1,600 ppm. Further, the amount of moisture in the PC sheet after being left in the environment for 25.0 hours was 3,500 ppm. The amount of moisture in the PC sheet was reduced by 54.4% by preliminary annealing. However, since the PC sheet, which had no hard coat, was left in the environment for 25.0 hours, the amount of moisture was returned to the amount before the preliminary annealing. A sample having a size of 300 mm×300 mm was cut out from the manufactured electromagnetic-wave reflecting panel 10. Then, a 720-hour endurance test was carried out in a constant-temperature bath having a temperature of 80° C. When the external appearance of the sample was observed after the endurance test, it was found that bubbles were formed over the entire surface.

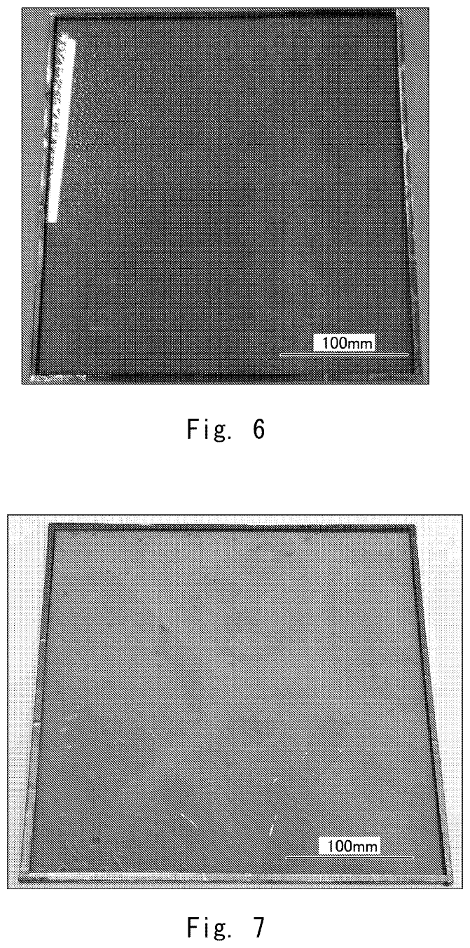

FIG. 6 shows the external appearance of the sample of Example 12 (Comparative Example 1) after the endurance test. Bubbles are clearly observed in the upper left area of the photograph. Although it is difficult to observe in the image due to the reflection of light rays or the like, fine bubbles are generated throughout the entire sample. It is considered that although the moisture contained in the PC sheet was evaporated to some extent by the preliminary annealing, moisture in the atmosphere entered the PC sheet because the PC sheet was left for 24 hours before the lamination process was started. The change in visible-light transmittance of the sample after the endurance test was-19.7%, and ΔE*ab was 12.1. Since bubbles are formed over the entire surface of the panel, the visibility (i.e., visibility through the panel) is insufficient, so that the panel cannot be used as a product.

### Example 13

Example 13 is Comparative Example 2. In Example 13, an electromagnetic-wave reflecting panel 10 having a layer structure shown in FIG. 4 was manufactured by using the same PC sheet as that of Example 1. No hard coat layer 17 was provided on the PC sheet. Prior to the lamination process, the PC sheet was subjected to preliminary annealing at 70° C. for 20.0 hours. After 1.0 hours from when the PC sheet was taken out from the constant-temperature bath for the preliminary annealing, an electromagnetic-wave reflecting panel 10 was manufactured by performing the same lamination process as that performed in Example 1. The amount of moisture in the PC sheet before the preliminary annealing was 3,520 ppm, and the amount of moisture in the PC sheet immediately after the completion of the preliminary annealing was 2,145 ppm (reduced by 39.0%). A sample having a size of 300 mm×300 mm was cut out from the manufactured electromagnetic-wave reflecting panel 10. Then, a 720-hour endurance test was carried out in a constant-temperature bath having a temperature of 80° C. When the external appearance of the sample was observed after the endurance test, it was found that long ridges were formed in a plurality of places in addition to bubbles formed throughout the entire sample.

FIG. 7 shows the external appearance of the sample of Example 13 (Comparative Example 2) after the endurance test. A number of slender and wavy air layers are observed in the lower half of the photograph. Although it is difficult to observe in the image due to the reflection of light rays or the like, bubbles are also generated throughout the entire sample. It is presumed that bubbles formed close to each other fused together and grew into slender and wavy bubbles. It is presumed that the temperature in the preliminary annealing for the PC sheet was low, so that moisture could not be sufficiently evaporated from the PC sheet. Since the lamination process was started one hour after the PC sheet was taken out from the constant-temperature bath for the preliminary annealing, the penetration of moisture from the environment into the PC sheet was limited. However, compared with Example 1, the temperature in the preliminary annealing was low, so that the adhesion between the PC sheet and the adhesive layer after the lamination process was insufficient. It is presumed that the moisture that was not removed from the PC sheet by the preliminary annealing and remained there was evaporated during the endurance test, so that the bubbles fused together and became slender ridges. The change in visible-light transmittance of the sample after the endurance test was −19.9%, and ΔE*ab was 12.2. The visibility was insufficient due to the ridges and bubbles on the panel surface, so that the panel cannot be used as a product.

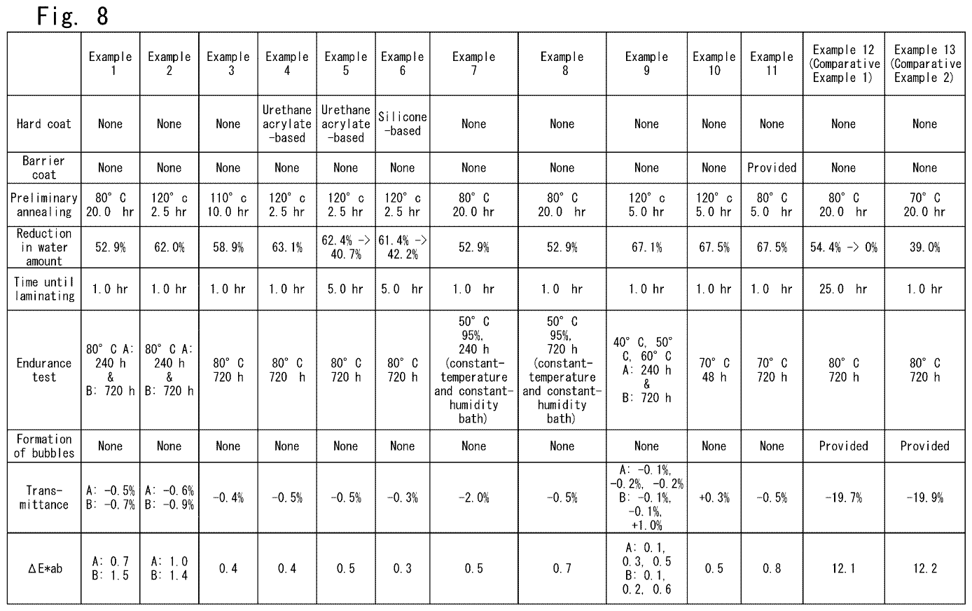

FIG. 8 shows a table in which the conditions and the measurement results of Examples 1 to 13 are summarized. The following matters are derived from the measurement results of Examples 1 to 13. (a) The absolute value of the amount of change in visible-light transmittance of the electromagnetic-wave reflecting panel after the endurance test in a constant-temperature bath having a temperature of 80° C. up to 720 hours is 10.0% or smaller, preferably 5% or smaller, more preferably 2.5% or smaller, and still more preferably 1.0% or smaller. The absolute value of the amount of change in visible-light transmittance of the electromagnetic-wave reflecting panel after the endurance test in a constant-temperature and constant-humidity bath having a temperature of 50° C. and a humidity of 95% up to 720 hours is 10.0% or smaller, preferably 5% or smaller, and more preferably 2.5% or smaller. (b) The color difference (ΔE*ab) of the electromagnetic-wave reflecting panel after the above-described endurance test using a constant-temperature bath or a constant-temperature and constant-humidity bath is 3.0 or smaller, preferably 2.0 or smaller, more preferably 1.5 or smaller, and still more preferably 1.0 or smaller. (c) It is possible to reduce the moisture contained in the resin substrate by 35% or more and thereby to prevent bubbles from being formed even after the endurance test by performing, prior to the lamination process of the electromagnetic-wave reflecting panel, preliminarily annealing for the resin substrate to be used at a temperature higher than 70° C. and equal to or lower than the heat-resistant temperature of the resin substrate. (c) By providing a hard coat layer on the surface of the resin substrate of the electromagnetic-wave reflecting panel, the penetration of moisture into the resin substrate is prevented, so that the above-described condition (a) or (b) can be easily satisfied. (e) The time of the preliminary annealing does not necessarily have to be long, and the annealing may be performed only for a short time at a relatively high temperature within the range of heat-resistant temperatures. (f) When a hard coat layer or a barrier coat layer is provided on the resin substrate, the penetration of moisture can be prevented even when the resin substrate is left in the environment for a relatively long time after being taken out from the constant-temperature bath for the preliminary annealing and then the lamination process is started. On the other hand, when a resin substrate including no hard coat layer nor barrier coat layer is used, it is desirable that the lamination process be performed within a predetermined time, for example, within 24 hours, preferably within several hours, and more preferably within one hour, after the resin substrate is taken out from the constant-temperature bath for the preliminary annealing.

In the case of the PC sheets used in Examples 1 to 11, the preliminary annealing is performed in a temperature range, for example, higher than 70° C. and equal to or lower than 130° C. When a flame-retardant acryl is used as a dielectric resin substrate, gas containing moisture and the like contained in the acrylic sheet is evaporated by performing preliminary annealing at a temperature, for example, higher than 70° C. and equal to or lower than 120° C., so that bubbles can be prevented from being formed even after an endurance test which is performed for 2 to 720 hours in a constant-temperature bath having a temperature of 60° C., 70° C., or 80° C., or even after an endurance test which is performed for 2 to 720 hours in a constant-temperature bath having a temperature of 50° C. and a humidity of 95%.

The penetration of gas containing moisture and the like from the adhesive layer into the acrylic sheet may be prevented by providing a hard coat layer or a barrier coat layer on at least the surface of the acrylic sheet on the side that is in contact with the adhesive layer. Even when COP or fiber-reinforced PET is used for the dielectric resin substrate, the preliminary annealing may be performed at a temperature, for example, higher than 70° C. and equal to or lower than 150° C. When a resin material having a higher heat-resistant temperature is used, the preliminary annealing may be performed at a temperature, for example, higher than 70° C. and equal to or lower than 180° C.

An ultraviolet-curable (UV-curable) coating agent other than the urethane acrylate-based ones may be used as the hard coat layer 17. As the UV-curable coating agent which is easily stretched and can be cured in a short time, a UV-curable coating agent such as an epoxy acrylate-based coating agent or a polyester acrylate-based coating agent may be used. In addition to the silicone-based coating agent, a fluorine-based coating agent may be used. In the case of the barrier coat layer, a fluororesin, PVA, or an ethylene-vinyl alcohol copolymer polyvinylidene chloride may be used as the coating agent, or a film formed by coating a transferable resin film with such an agent may be used.

In the case where no hard coat layer nor barrier coat layer is provided on the resin substrate, the method for manufacturing an electromagnetic-wave reflecting panel includes:
performing preliminary annealing for a dielectric resin substrate at a temperature higher than 70° C. and within a range of heat-resistant temperatures of this resin substrate;
manufacturing an electromagnetic-wave reflecting panel by bonding the resin substrate, for which the preliminary annealing has been performed, to a reflecting function layer within a predetermined time, for example, within 24 hours, preferably within several hours, and more preferably within one hour from the completion of the preliminary annealing; and
reducing the amount of gas containing moisture and the like contained in the resin substrate by 35% or more and preferably 40% or more by the preliminary annealing. By this method, the gas containing moisture and the like contained in the resin substrate is evaporated, so that the formation of bubbles, the occurrence of peeling, and the occurrence of swelling can be prevented even after an endurance test up to 720 hours in a constant-temperature bath having a temperature of 80° C. or an endurance test up to 720 hours in a constant-temperature and constant-humidity bath having a temperature of 50° C. and a humidity of 95%.

In the case where a hard coat layer or a barrier coat layer is provided on the resin substrate, the method for manufacturing an electromagnetic-wave reflecting panel includes:
forming a hard coat layer or a barrier coat layer on at least one of the surfaces of a dielectric resin substrate;
performing preliminary annealing for the resin substrate including the hard coat layer or the barrier coat layer at a temperature higher than 70° C. and within a range of heat-resistant temperatures of this resin substrate; and
manufacturing an electromagnetic-wave reflecting panel by bonding the surface of the resin substrate which has been subjected to the preliminary annealing and on which the hard coat layer or the barrier coat layer has been formed to a reflecting function layer. In this method, the penetration of gas containing moisture and the like into the resin substrate is prevented by the hard coat layer or the barrier coat layer, so that the formation of bubbles, the occurrence of peeling, and the occurrence of swelling can be prevented even after an endurance test up to 720 hours in a constant-temperature bath having a temperature of 80° C. or an endurance test up to 720 hours in a constant-temperature and constant-humidity bath having a temperature of 50° C. and a humidity of 95%.

Embodiments according to the present disclosure have been described above, but the present disclosure may also include configurations described hereinafter.

### (Item 1)

An electromagnetic-wave reflecting panel is an electromagnetic-wave reflecting panel configured to reflect an electromagnetic wave in a predetermined frequency band of 1 MHz or higher and 300 GHz or lower, comprising: a reflecting function layer configured to selectively reflect the electromagnetic wave in the predetermined frequency band; and a dielectric resin substrate configured to support the reflecting function layer, wherein an amount of change in visible-light transmittance of the electromagnetic-wave reflecting panel after an endurance test in which the electromagnetic-wave reflecting panel is put in a constant-temperature bath having a temperature of 40° C. to 80° C. for 2 to 720 hours or in a constant-temperature and constant-humidity bath having a temperature of 50° C. and a humidity of 95% for 2 to 720 hours is 10% or smaller, and ΔE*ab is 3.0 or smaller.

### (Item 2)

The electromagnetic-wave reflecting panel described in Item 1, wherein the amount of change in visible-light transmittance of the electromagnetic-wave reflecting panel after the endurance test is 5.0% or smaller and is preferably 2.5% or smaller.

### (Item 3)

The electromagnetic-wave reflecting panel described in Item 1 or 2, wherein ΔE*ab of the electromagnetic-wave reflecting panel after the endurance test is 2.0 or smaller and is preferably 1.5 or smaller.

### (Item 4)

The electromagnetic-wave reflecting panel described in any one of Items 1 to 3, further comprising an adhesive layer provided between the resin substrate and the reflecting function layer, wherein the resin substrate includes a hard coat layer or a barrier coat layer on a surface thereof that is in contact with the adhesive layer.

### (Item 5)

The electromagnetic-wave reflecting panel described in any one of Items 1 to 3, wherein the resin substrate includes a hard coat layer or a barrier coat layer on each of both surfaces.

### (Item 6)

The electromagnetic-wave reflecting panel described in any one of Items 1 to 5, wherein the resin substrate includes a first resin substrate and a second resin substrate configured to sandwich the reflecting function layer therebetween, and the first and second resin substrates are bonded to both surfaces of the reflecting function layer.

### (Item 7)

An electromagnetic-wave reflecting apparatus comprising:
an electromagnetic-wave reflecting panel described in any one of Items 1 to 6; and
a frame configured to hold the electromagnetic-wave reflecting panel.

### (Item 8)

An electromagnetic-wave reflecting fence obtained by connecting a plurality of electromagnetic-wave reflecting apparatuses each of which is one described in Item 7 with one another by the frame.

### (Item 9)

A method for manufacturing an electromagnetic-wave reflecting panel, comprising:
performing preliminary annealing for a dielectric resin substrate at a temperature higher than 70° C. and within a range of heat-resistant temperatures of the resin substrate;
manufacturing the electromagnetic-wave reflecting panel by bonding the resin substrate, for which the preliminary annealing has been performed, to a reflecting function layer within a predetermined time from completion of the preliminary annealing; and
reducing an amount of gas containing moisture contained in the resin substrate by 35% or more.

### (Item 10)

A method for manufacturing an electromagnetic-wave reflecting panel, comprising:
forming a hard coat layer or a barrier coat layer on at least one of surfaces of a dielectric resin substrate;
performing preliminary annealing for the resin substrate including the hard coat layer or the barrier coat layer at a temperature higher than 70° C. and within a range of heat-resistant temperatures of the resin substrate; and
manufacturing the electromagnetic-wave reflecting panel by bonding a surface of the resin substrate which has been subjected to the preliminary annealing and on which the hard coat layer or the barrier coat layer has been formed to a reflecting function layer.

### (Item 11)

A method for evaluating an electromagnetic-wave reflecting panel configured to reflect an electromagnetic wave in a predetermined frequency band of 1 MHz or higher and 300 GHz or lower, wherein
the electromagnetic-wave reflecting panel comprises:
a reflecting function layer configured to selectively reflect the electromagnetic wave in the predetermined frequency band; and
a dielectric resin substrate configured to support the reflecting function layer, and
it is evaluated whether an amount of change in visible-light transmittance of the electromagnetic-wave reflecting panel after an endurance test in which the electromagnetic-wave reflecting panel is put in a constant-temperature bath having a temperature of 40° C. to 80° C. for 2 to 720 hours or in a constant-temperature and constant-humidity bath having a temperature of 50° C. and a humidity of 95% for 2 to 720 hours is 10% or smaller, and whether ΔE*ab is 3.0 or smaller.

These embodiments can be combined as desirable by one of ordinary skill in the art. From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. An electromagnetic-wave reflecting panel configured to reflect an electromagnetic wave in a predetermined frequency band of 1 MHz or higher and 300 GHz or lower, comprising:
a reflecting function layer configured to selectively reflect the electromagnetic wave in the predetermined frequency band; and
a dielectric resin substrate configured to support the reflecting function layer, wherein
an amount of change in visible-light transmittance of the electromagnetic-wave reflecting panel after an endurance test in which the electromagnetic-wave reflecting panel is put in a constant-temperature bath having a temperature of 40° C. to 80° C. for 2 to 720 hours or in a constant-temperature and constant-humidity bath having a temperature of 50° C. and a humidity of 95% for 2 to 720 hours is 10% or smaller, and ΔE*ab is 3.0 or smaller.

2. The electromagnetic-wave reflecting panel according to claim 1, wherein the amount of change in visible-light transmittance of the electromagnetic-wave reflecting panel after the endurance test is 5.0% or smaller.

3. The electromagnetic-wave reflecting panel according to claim 1, wherein ΔE*ab of the electromagnetic-wave reflecting panel after the endurance test is 2.0 or smaller.

4. The electromagnetic-wave reflecting panel according to claim 1, further comprising an adhesive layer provided between the resin substrate and the reflecting function layer, wherein
the resin substrate includes a hard coat layer or a barrier coat layer on a surface thereof that is in contact with the adhesive layer.

5. The electromagnetic-wave reflecting panel according to claim 1, wherein the resin substrate includes a hard coat layer or a barrier coat layer on each of both surfaces.

6. The electromagnetic-wave reflecting panel according to claim 1, wherein
the resin substrate includes a first resin substrate and a second resin substrate configured to sandwich the reflecting function layer therebetween, and
the first and second resin substrates are bonded to both surfaces of the reflecting function layer.

7. An electromagnetic-wave reflecting apparatus comprising:
an electromagnetic-wave reflecting panel according to claim 1; and
a frame configured to hold the electromagnetic-wave reflecting panel.

8. An electromagnetic-wave reflecting fence obtained by connecting a plurality of electromagnetic-wave reflecting apparatuses each of which is one according to claim 7 with one another by the frame.

9. A method for manufacturing an electromagnetic-wave reflecting panel, comprising:
performing preliminary annealing for a dielectric resin substrate at a temperature higher than 70° C. and within a range of heat-resistant temperatures of the resin substrate;
manufacturing the electromagnetic-wave reflecting panel by bonding the resin substrate, for which the preliminary annealing has been performed, to a reflecting function layer within a predetermined time from completion of the preliminary annealing; and
reducing an amount of gas containing moisture contained in the resin substrate by 35% or more.

10. A method for manufacturing an electromagnetic-wave reflecting panel, comprising:
forming a hard coat layer or a barrier coat layer on at least one of surfaces of a dielectric resin substrate;
performing preliminary annealing for the resin substrate including the hard coat layer or the barrier coat layer at a temperature higher than 70° C. and within a range of heat-resistant temperatures of the resin substrate; and
manufacturing the electromagnetic-wave reflecting panel by bonding a surface of the resin substrate which has been subjected to the preliminary annealing and on which the hard coat layer or the barrier coat layer has been formed to a reflecting function layer.
